(19) United States
(12) Patent Application Publication
(10) Pub. No.: US 2010/0184255 A1
(43) Pub. Date: Jul. 22, 2010

(54) MANUFACTURING METHOD FOR PACKAGE STRUCTURE

(76) Inventors: Chien LIU, Kaohsiung City (TW); Wen-Yuen Chuang, Kaohsiung City (TW); Chung-Yao Kao, Kaohsiung City (TW); Tsang-Hung Ou, Kaohsiung City (TW); Chih-Huang Chang, Yongkang City (TW); Wei-Chi Yih, Taichung City (TW); Chen-Chuan Fan, Dali City (TW)

Correspondence Address: Muncy, Geissler, Olds & Lowe, PLLC, 4000 Legato Road, Suite 310, FAIRFAX, VA, 22033, US

(21) Appl. No.: 12/550,959

(22) Filed: Aug. 31, 2009

Related U.S. Application Data
(60) Provisional application No. 61/146,384, filed on Jan. 22, 2009.

(30) Foreign Application Priority Data
Apr. 10, 2009 (TW) 98112037

(51) Int. Cl. H01L 21/56

(52) U.S. Cl. 438/113; 257/E21.502

(57) ABSTRACT

A manufacturing method for package structure is provided. The manufacturing method includes the follow steps. Firstly, a substrate is provided. Next, a number of chips are provided. Then, the chips are electrically connected with the substrate. After that, the chips are encapsulated with a sealant, so that the chips and the substrate form a package. Then, the package is adhered by a vacuum force. Afterwards, the adhered package is singulated to form many package structures along the portion between adjacent two of airways.

This application claims the benefit of U.S. provisional application Ser. No. 61/146,384 filed Jan. 22, 2009, the subject matter of which is incorporated herein by reference, and claims the benefit of Taiwan application Serial No. 98112037, filed Apr. 10, 2009, the subject matter of which is incorporated herein by reference.

### BACKGROUND OF THE INVENTION

1. Field of the Invention

The invention relates in general to a manufacturing method for package structure, and more particularly to a manufacturing method for semiconductor package structure.

2. Description of the Related Art

During the process of manufacturing a semiconductor package structure, after the chips are electrically connected with the substrate, the chips and the substrate are encapsulated with a sealant to form a package first, and then the package is further singulated to form many package structures.

According to a generally known singulating method, the package is adhered to a tape such as a UV-light tape first and then the package is singulated to form many package structures. After the singulating process is completed, the package structures adhered to the tape are further irradiated by the UV light and then the package structures are picked and placed for further processing.

However, the above generally known singulating method has many disadvantages exemplified below.

Firstly, before the package is adhered to the tape, the tape must be adhered to a frame manually, which is very labor consuming and costly.

Secondly, as the tape must be manually adhered to a frame, such singulating method causes production capacity to become low due to manual operation.

Thirdly, the package structure is irradiated by the UV light after singulation, so the above generally known singulating method involves the procurement cost and maintenance for the UV light facility and requires extra space for the UV light facility.

Fourthly, at least three machines are required for attaching the tape to the frame, singulating the package structure, irradiating the package structure using UV light, and picking and placing the package structure. The three machines are the singulating machine, the UV light irradiating machine and the picking and placing machine, respectively. Such many machines will occupy a large space and incur a lot of cost.

### SUMMARY OF THE INVENTION

The invention is directed to a manufacturing method for package structure. The method of the invention includes the step of singulating a package to form many package structures without using a tape which is otherwise used in generally know technologies, hence saving the cost and time used for attaching the tape. Moreover, the UV light facility can even be omitted, and the overall cost is further reduced.

According to a aspect of the present invention, a manufacturing method for package structure is provided. The manufacturing method includes the following steps. Firstly, a substrate is provided. Next, a number of chips are provided. Then, the chips are electrically connected with the substrate. After that, the chips are encapsulated with a sealant, so that the chips and the substrate form a package. Then, a package is disposed on a vacuum platform, so that the package is adhered to the vacuum platform by a vacuum force of the vacuum platform. The vacuum platform has a number of airways disposed therein, and the positions of the airways are aligned to those of the chips. The package is singulated along a cutting path passing through a portion between adjacent two of the airways.

The invention will become apparent from the following detailed description of the preferred but non-limiting embodiments. The following description is made with reference to the accompanying drawings.

### BRIEF DESCRIPTION OF THE DRAWINGS

FIG. 1 shows a flowchart of manufacturing method for package structure according to a preferred embodiment of the invention;

FIG. 2 shows a substrate provided in step S102 of FIG. 1;

FIG. 3 shows the substrate of FIG. 2 and several chips;

FIG. 4 shows the chips of FIG. 3 being electrically connected with a substrate;

FIG. 5 shows the chips and second conductive portions of FIG. 4 being encapsulated;

FIG. 6 shows the substrate of FIG. 5 having several first conductive portions disposed thereon;

FIG. 7 shows the substrate of FIG. 6 being fixed;

FIG. 8 shows a vacuum platform according to another embodiment of the invention;

FIG. 9 shows a vacuum platform according to yet another embodiment of the invention;

FIG. 10 shows a package of the invention being singulated; and

FIG. 11 shows a top view of a package viewed along a direction V1 of FIG. 10.

### DETAILED DESCRIPTION OF THE INVENTION

According to the manufacturing method for package structure of the invention, a package, being adhered to a vacuum platform by a vacuum force, is singulated to form many package structures. Compared with generally known technologies, the method of the invention can be accomplished without using a tape, hence saving the cost and time used for attaching the tape. Moreover, the UV light facility can even be omitted, and the overall cost is further reduced.

A number of preferred embodiments are disclosed below for elaboration purpose. However, the embodiments are examples of implementation under the spirit of the invention, and the disclosure and drawings of the embodiments are not for limiting the scope of protection of the invention.

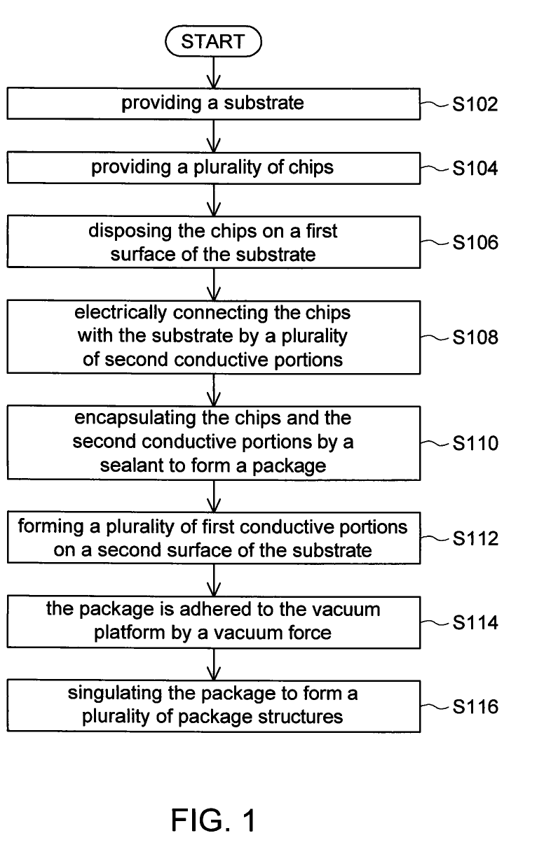

Referring to FIG. 1, a flowchart of manufacturing method for package structure according to a preferred embodiment of the invention is shown. The manufacturing method for package structure includes the following steps.

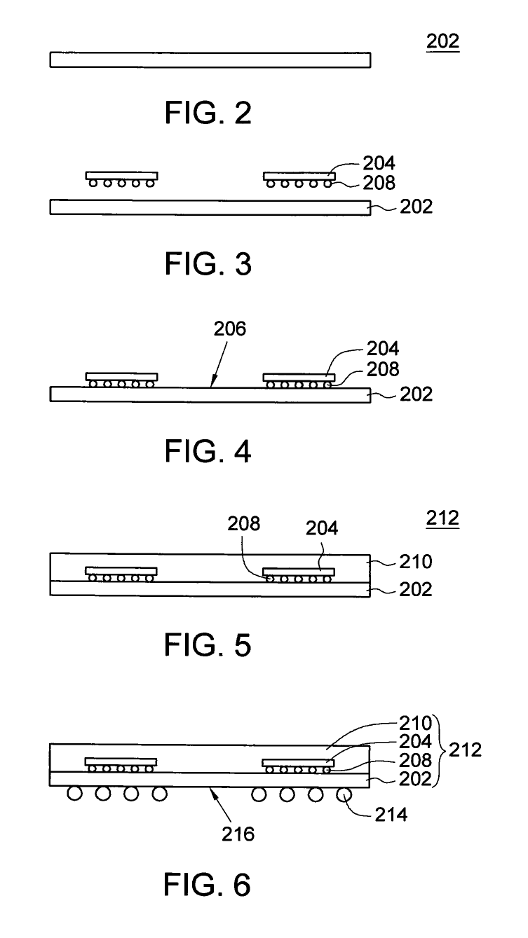

Firstly, in step S102, a substrate 202 is provided. Referring to FIG. 2, a substrate provided in step S102 of FIG. 1 is shown.

Next, in step S104, a number of chips 204 are provided. Referring to FIG. 3, the substrate of FIG. 2 and several chips are shown. The chip 204 is a flip chip, and has a number of second conductive portions 208 such as solder balls disposed thereon for electrically connecting the chip 204 with the substrate 202.

Then, in step S106, the chip 204 is disposed on a first surface 206 of the substrate 202. Then, at step S108, the chip 204 is electrically connected with the substrate 202 by the second conductive portions 208 disposed on the chip 204. As indicated in FIG. 4, the chips of FIG. 3 are electrically connected with a substrate.

Then, in step S110, the chips 204 and the second conductive portions 208 are encapsulated with a sealant 210, so that the substrate 202, the chip 204, the sealant 210, and the second conductive portions 208 form a package 212. As indicated in FIG. 5, the chips and the second conductive portions of FIG. 4 are encapsulated.

Then, in step S112, a number of first conductive portions 214 are formed on a second surface 216 of the substrate 202. As indicated in FIG. 6, the substrate of FIG. 5 has several first conductive portions such as solder balls disposed thereon.

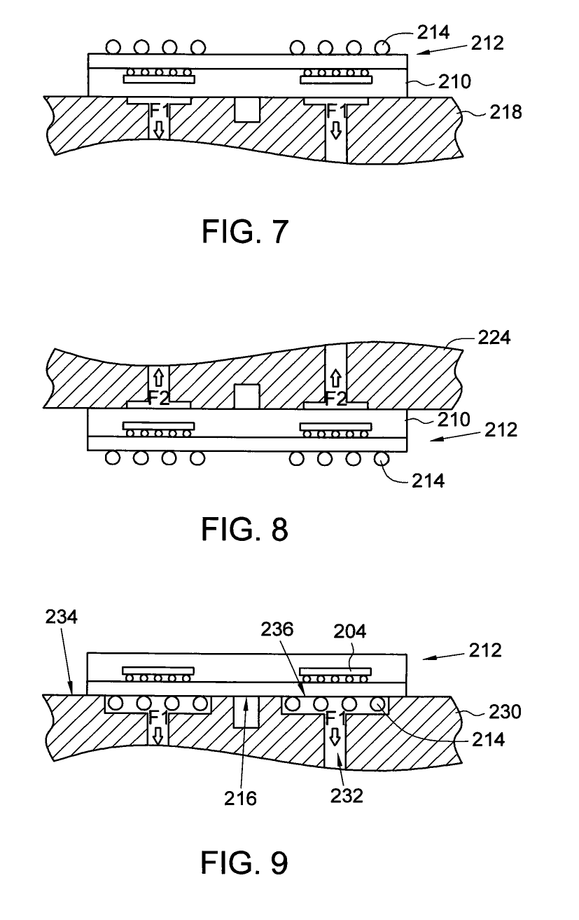

Referring to FIG. 7, which shows the package 212 of FIG. 6 is adhered to a vaccum platform 218. In step S114, the package 212 is adhered to the vacuum platform 218 by a vacuum force F1, such that the package 212 is securely attached to the vacuum platform 218. Thus, in the subsequent singulating step, the singulated package 212 will not come off the vacuum platform 218. The value of the negative pressure of the vacuum force F1 can be −70 kpa or other values. As long as the package 212 is firmly adhered to the vacuum platform 218 by the vacuum force F1, the value of the negative pressure can be any value and is not restricted by the present embodiment of the invention.

Preferably but not exclusively, the vacuum platform 218 includes a flexible member (not illustrated) made from rubber, for example. When the package 212 is adhered to the vacuum platform 218, the flexible member is used for contacting the package 212 to prevent the package 212 from abrasive damage due to the contact between the sealant 210 and the vacuum platform 218.

Before the package 212 is disposed on the vacuum platform 218, the package 212 can be inverted so that the sealant 210 of the package 212 faces the vacuum platform 218. Thus, the sealant 210 of the package 212 is adhered to the vacuum platform 218. As the outer surface of the sealant 210 does not possess any circuit structure, the way of adhering the sealant 210 of the package 212 does not damage structures with electrical function (such as the first conductive portion 214).

Despite the package 212 is inverted in the present embodiment of the invention, the package 212 can also be adhered to the vacuum platform without inverting the package 212. Referring to FIG. 8, a vacuum platform according to another embodiment of the invention is shown. The vacuum platform 224 of another embodiment can adhere the sealant 210 of the package 212 of FIG. 6 without inverting the package 212. Furthermore, the vacuum platform 218 (the vacuum platform 218 is illustrated in FIG. 7) can be modified such that the vacuum platform 224 adheres the package 212 in the direction of the vacuum force F2, which is opposite of that of the vacuum force F1. The package 212 is disposed underneath the vacuum platform 224, and then the vacuum platform 224 directly the package 212 from the top.

Referring to FIG. 9, a vacuum platform according to another embodiment of the invention is shown. The package 212 is disposed on the vacuum platform 230, and the second surface 216 of the package 212 is adhered to the vacuum platform 230. The vacuum platform 230 has a number of airways 232 disposed therein. The airways 232 are interconnected with a vacuum source (not illustrated) and expose a number of openings 236 on the surface 234 of the vacuum platform 230. The positions of the openings 236 are aligned to those of the chip 204, and the area of the opening 236 is larger than the area occupied by the first conductive portions 214 so that the first conductive portions 214 are disposed inside the opening 236. As each chip 204 corresponds to an opening 236, the package 212 is still firmly adhered to the vacuum platform 230 after singulation and then waits for subsequent processing.

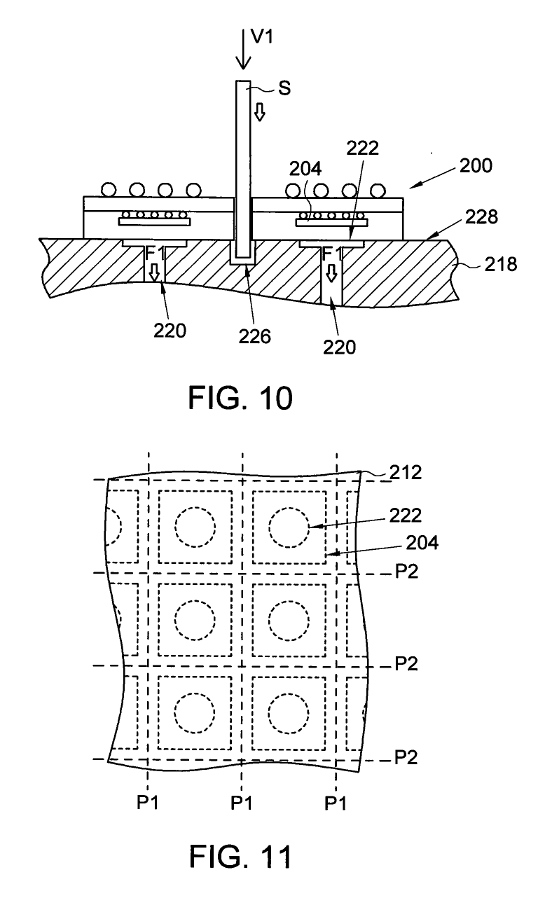

Referring to both FIG. 10, a package of the invention is singulated. and in step S116, the package 212 of FIG. 7 is singulated by a cutting tool S, such as a saw, along the portion between adjacent two of airways 220 to form a number of package structures 200. The package structure 200, for example, is a semiconductor structure.

As the package 212 is securely adhered by the vacuum force F1 of the vacuum platform 218 during the singulating process, the undesirable events of the package structures 200 flying off the vacuum platform 218 can be avoided.

The vacuum platform 218 has a number of airways 220 disposed therein. The airways 220 are interconnected with a vacuum source and expose a number of openings 222 on the surface 228 of the vacuum platform 218. The positions of the openings 222 are aligned to those of the chips 204. That is, each chip 204 corresponds to an opening 222, so that, after the singulating process is completed, each of the package structures 200 is still firmly adhered to the vacuum platform 218 and waits for subsequent processing.

As indicated in FIG. 10, the vacuum platform 218 further has a slot 226 disposed in the portion between adjacent two of the airways 220. The cutting tool S passes through the slot 226 so that two package structures 200 are completely separated without damaging the surface of the vacuum platform 218.

Referring to FIG. 11, a top view of a package viewed along a direction V1 of FIG. 10 is shown. During the singulating process, the package 212 is singulated along the first cutting path P1 and the second cutting path P2, wherein both the first cutting path P1 and the second cutting path P2 pass through a portion between adjacent two of the chips 204. In singulating step S116, the package 212 can be singulated along the first cutting path P1 and the second cutting path P2 by single cutting tool only. Or, the package 212 can be singulated by more than one cutting tool along the first cutting path P1 and the second cutting path P2 respectively. Or, the package 212 is singulated by more than one cutting tool along the first cutting path P1 first, and then the package 212 is singulated along the second cutting path P2. The present embodiment of the invention does not restrict the number of cutting tool S used for singulating the package 212, the sequence or the way of singulating the package 212. The number of cutting tool S, the sequence and the way of singulating the package 212 are determined according to the production capacity, the manufacturing facility and other requirements.

According to the manufacturing method of the package structure of the present embodiment of the invention, the singulating step can be accomplished without using a tape which is normally needed in conventional technologies, so the labor for attaching the tape is omitted. Also, the design of securely attaching the package structure by a vacuum force not only omits the steps of attaching the package to the tape and irradiating the package structure using the UV light but also integrates the operations of singulating, picking and placing the package into the same machine, such as a machine having a vacuum platform 218 or 224, for example. Thus, considerable costs of facility procurement and maintenance are saved. Moreover, no labor is involved during the process of singulating the package 212, and this is very helpful to achieve full automatic production line. Thus, the manufacturing method of the package structure 200 of the present embodiment of the invention, which shortens manufacturing time and reduces the demand for labor, is ideal for large scale production and largely increases production capability.

Despite the chip 204 of the present embodiment of the invention is exemplified by a flip chip, however, in another embodiment, the chip 204 does not have to be a flip chip. For example, the chip 204 has a number of pads (not illustrated), and the pads disposed on the chip 204 are electrically connected with the substrate 202 by a number of bonding wires (not illustrated). The bonding wires and the pads are both encapsulated by the sealant 210.

The manufacturing method for package structure disclosed in the above embodiments of the invention has many advantages exemplified below.

Firstly, the singulating step of the manufacturing method of the package structure of the present embodiment of the invention can be accomplished without using a tape which is normally needed in conventional technologies, hence saving the cost of the tape and the time used for attaching the tape.

Secondly, the singulating step of the package structure can be accomplished by a single machine such as a machine having a vacuum platform 218 or 224. Moreover, no labor is involved during the process of singulating the package, and this is very helpful to the total automation of the production line. Thus, the manufacturing method of the package structure of the present embodiment of the invention is ideal for large scale production and largely increases production capability.

Thirdly, the manufacturing method for package structure disclosed in the above embodiments not only omits the steps of attaching the package to the tape and irradiating the package structure using the UV light but also integrating the step of singulating the package and picking and placing materials for the package structure 200 into the same machine such as a machine having a vacuum platform 218 or 224. Thus, considerable costs of facility procurement and maintenance are saved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method for package structure, comprising:
providing a substrate;
providing a plurality of chips;
electrically connecting the chips with the substrate;
encapsulating the chips with a sealant, so that the sealant, the chips and the substrate form a package;
disposing the package on a vacuum platform, so that the package is adhered to the vacuum platform by a vacuum force of the vacuum platform, wherein the vacuum platform has a plurality of airways disposed therein, and the positions of the airways are aligned to those of the chips; and
singulating the package along a cutting path which passes through a portion between adjacent two of the airways.

2. The manufacturing method according to claim 1, wherein prior to the step of electrically connecting the chips with the substrate, the manufacturing method further comprises:
disposing the chips on a first surface of the substrate; and
after the step of encapsulating the chips with a sealant and prior to the step of disposing the package on the vacuum platform, the manufacturing method further comprises:
forming a plurality of first conductive portions on a second surface of the substrate, wherein the second surface is opposite to the first surface.

3. The manufacturing method according to claim 1, wherein the portion between adjacent two of the airways has a slot for a cutting tool to pass through.

4. The manufacturing method according to claim 1, wherein the vacuum platform comprises a flexible member for contacting the package when the package is adhered to the vacuum platform.

5. The manufacturing method according to claim 1, wherein a negative pressure of the vacuum force is substantially −70 kpa.

6. The manufacturing method according to claim 1, wherein the step of singulating the package is performed by a cutting tool.

7. The manufacturing method according to claim 2, wherein in the step of disposing the package on the vacuum platform, the sealant of the package is adhered to the vaccum platform.

8. The manufacturing method according to claim 7, wherein prior to the step of disposing the package on the vacuum platform, the manufacturing method further comprises:
inverting the package, such that the sealant of the package faces towards the vacuum platform.

9. The manufacturing method according to claim 2, wherein in the step of disposing the package on the vacuum platform, the second surface of the substrate is adhered to the vaccum platform.

10. The manufacturing method according to claim 9, wherein each of the airways has an opening exposed on the surface of the vacuum platform, and the first conductive portions are disposed inside the opening.
